(19) United States
(12) Patent Application Publication
(10) Pub. No.: US 2025/0204011 A1
(43) Pub. Date: Jun. 19, 2025

(54) SEMICONDUCTOR DEVICES AND METHOD OF MANUFACTURING THE SAME

(71) Applicant: SAMSUNG ELECTRONICS CO., LTD, SUWON-SI (KR)

(72) Inventors: Seongdong Lim, Suwon-si (KR); Chunghwan Shin, Suwon-si (KR); Seongheum Choi, Suwon-si (KR); Jiwon Kang, Suwon-si (KR); Daeun Kim, Suwon-si (KR); Jeongik Kim, Suwon-si (KR)

(21) Appl. No.: 18/918,415

(22) Filed: Oct. 17, 2024

(30) Foreign Application Priority Data
Dec. 14, 2023 (KR) 10-2023-0182203

(51) Int. Cl. H01L 29/45; H01L 21/285; H01L 21/321; H01L 29/06; H01L 29/417; H01L 29/423; H01L 29/66; H01L 29/775; H01L 29/786

(52) U.S. Cl. CPC H10D 64/62; H01L 21/2855; H01L 21/28556; H01L 21/3212; H10D 30/014; H10D 30/43; H10D 30/6729; H10D 30/6735; H10D 30/6757; H10D 62/121; H10D 64/017

(57) ABSTRACT

The semiconductor device includes a substate, a gate structure on the substrate, a source/drain layer on the substrate adjacent to the gate structure, and a contact plug. The contact plug includes a barrier pattern on the source/drain layer, a first liner on the barrier pattern, a second liner on the first liner and including a metal, a conductive pattern on the second liner and including the metal. The first liner includes a first portion extending along a surface of the barrier pattern and having a first grain size, and a second portion extending from the first portion disposed on an end portion of the barrier pattern, the second portion being in contact with the first portion and having a second grain size greater than the first grain size.

### CROSS-REFERENCE TO RELATED APPLICATION

This application claims priority under 35 U.S.C. § 119 to Korean Patent Application No. 10-2023-0182203, filed on Dec. 14, 2023, in the Korean Intellectual Property Office, the disclosure of which is hereby incorporated by reference in its entirety.

### TECHNICAL FIELD

Example embodiments of the present disclosure relate to a semiconductor device and a method of manufacturing the same. More particularly, example embodiments of the present disclosure relate to a semiconductor device having a contact plug and a method of manufacturing the same.

### DISCUSSION OF RELATED ART

In a semiconductor device, a contact plug may be electrically connected to a source/drain layer and may include a conductive pattern and a barrier pattern covering the conductive pattern. As a grain size of the conductive pattern decreases, a resistance of the conductive pattern may increase, and an overall resistance of the contact plug including the conductive pattern may increase.

### SUMMARY

Example embodiments provide a semiconductor device having an improved characteristic.

Example embodiments provide a method of manufacturing a semiconductor device having an improved characteristic.

According to example embodiments, there is provided a semiconductor device. The semiconductor device may include a substrate, a gate structure disposed on the substrate, a source/drain layer disposed on the substrate adjacent to the gate structure, and a contact plug. The contact plug may include a barrier pattern, a first liner, a second liner, a conductive pattern. The barrier pattern may be disposed on the source/drain layer. The first liner may be disposed on the barrier pattern. The first liner may include a first portion which may extend along a surface of the barrier pattern and have a first grain size, and a second portion which may extend from the first portion disposed on an end portion of the barrier pattern, be in contact with the first portion, and may have a second grain size greater than the first grain size. The second liner may be disposed on the first liner and include a metal. The conductive pattern may be disposed on the second liner, and include the metal.

According to example embodiments, there is provided a semiconductor device. The semiconductor device may include a substrate, a plurality of channels disposed on the substrate, the plurality of channels spaced apart from each other in a vertical direction substantially perpendicular to an upper surface of the substrate, a gate structure disposed on the substrate, the gate structure surrounding an upper surface, a lower surface, and a sidewall surface of a portion of each of the plurality of channels, a source/drain layer disposed on the substrate at opposite sides of the gate structure, an insulating interlayer disposed on the source/drain layer, and a contact plug extending through the insulating interlayer and contacting an upper surface of the source/drain layer. The contact plug may include a conductive pattern including a metal, a second liner which may cover a lower surface and a sidewall of the conductive pattern, and include the metal in an amorphous state, and a first liner. The first liner may include a first portion, which may cover a lower surface and a lower sidewall of the second liner, and include the metal having a first grain size, and a second portion, which may extend from the first portion and contact the first portion. The second portion of the first liner may cover an upper sidewall of the second liner and include the metal having a second grain size greater than the first grain size. The contact plug may include a barrier pattern covering a lower surface and a sidewall of the first portion of the first liner.

According to example embodiments, there is provided a method of manufacturing a semiconductor device. The method of manufacturing the semiconductor device may include forming a gate structure and a source/drain layer on a substrate, forming an insulating interlayer on the substrate to cover an upper surface of the source/drain layer and a sidewall of the gate structure, removing a portion of the insulating interlayer to form an opening exposing the upper surface of the source/drain layer, forming a barrier pattern on a bottom and a lower sidewall of the opening and exposing a portion of the insulating interlayer forming an upper sidewall of the opening, forming a first liner layer on the barrier pattern and the upper sidewall of the opening by a physical vapor deposition (PVD) process, forming a second liner layer on the first liner layer by an atomic layer deposition (ALD) process, and forming a conductive pattern on the second liner layer.

In the semiconductor device in accordance with example embodiments, a contact plug may include a barrier pattern, a first liner, a second liner and a conductive pattern, and the conductive pattern may be disposed on the second liner, which may include a metal in an amorphous state, to have a relatively large grain size. Thus, the conductive pattern may have a low resistance. Accordingly, the contact plug including the conductive pattern and the semiconductor device including the same may have an improved electrical characteristic.

### BRIEF DESCRIPTION OF THE DRAWINGS

FIGS. 1 to 4 are a plan view and cross-sectional views illustrating a semiconductor device in accordance with example embodiments.

FIGS. 5 to 22 are plan views and cross-sectional views illustrating a method of manufacturing a semiconductor device in accordance with example embodiments.

FIG. 23 is a cross-sectional view illustrating a semiconductor device in accordance with example embodiments.

FIGS. 24 and 25 are cross-sectional views illustrating a method of manufacturing a semiconductor device in accordance with example embodiments.

### DETAILED DESCRIPTION

Hereinafter, example embodiments will be explained in detail with reference to the accompanying drawings.

Aspects and features of a semiconductor device and a method of manufacturing the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

Hereinafter, in the specification (and not necessarily in the claims), a first direction D1 and a second direction D2 may be substantially perpendicular to each other, and may be substantially parallel to an upper surface of a substrate. Further, a third direction D3 may be a vertical direction substantially perpendicular to the upper surface of the substrate. In example embodiments, the first and second directions D1 and D2 may be orthogonal to each other. Each of the first to third directions D1, D2 and D3 may represent not only a direction shown in the drawing, and/or a reverse direction.

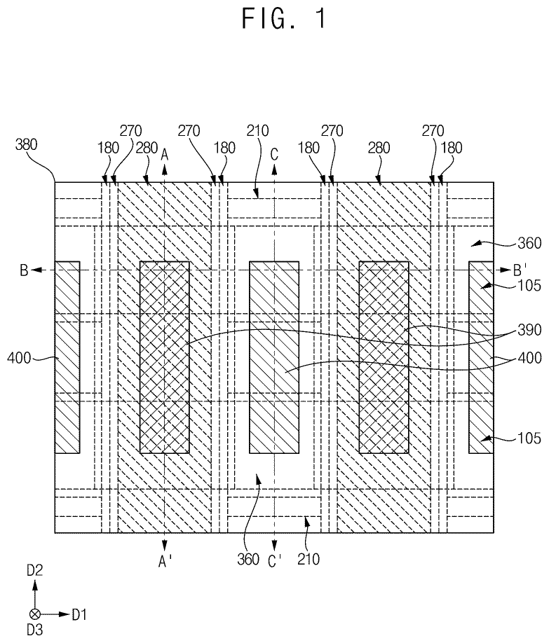

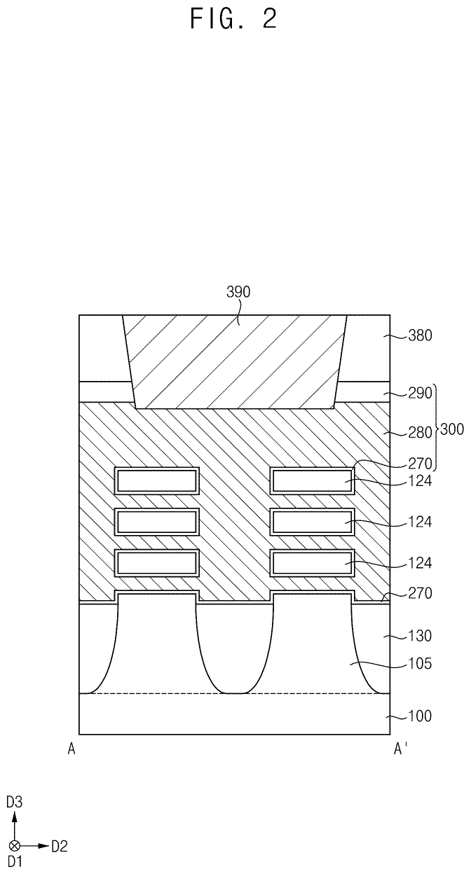

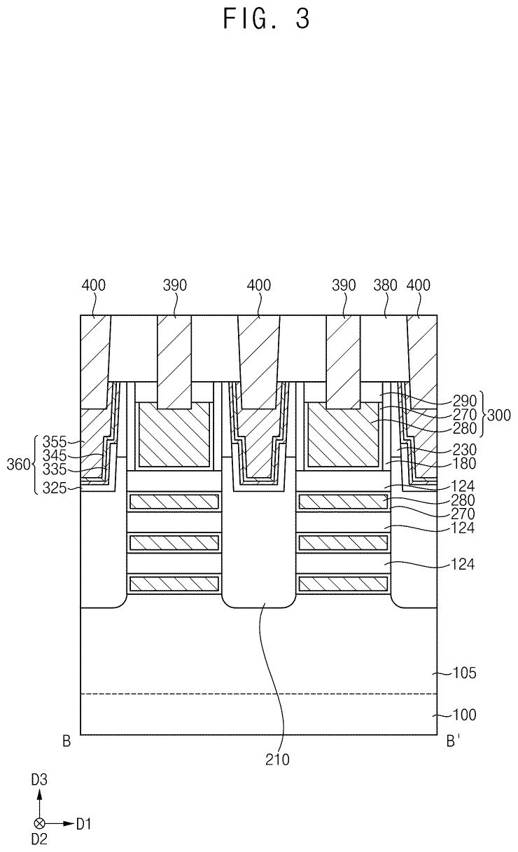

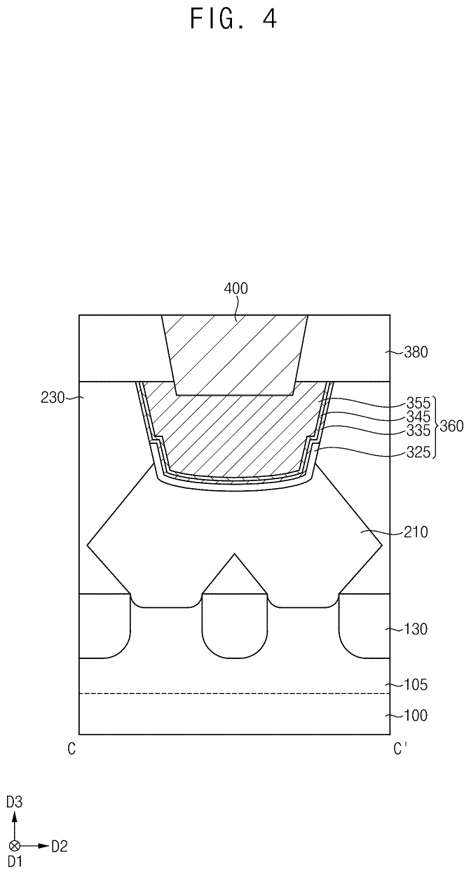

FIGS. 1 to 4 are a plan view and cross-sectional views illustrating a semiconductor device in accordance with example embodiments. Specifically, FIG. 1 is the plan view illustrating a semiconductor device in accordance with example embodiments, and FIG. 2, FIG. 3, and FIG. 4 are cross-sectional views illustrating a semiconductor device in accordance with example embodiments. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1.

Referring to FIGS. 1 to 4, the semiconductor device may include an active pattern 105, an isolation pattern 130, semiconductor patterns 124, a gate spacer 180, a source/drain layer 210, a gate structure 300, a first contact plug 360, a second contact plug 390, a first insulating interlayer 230, a second insulating interlayer 380, and a via 400.

A substrate 100 may be provided. The substrate 100 may include a semiconductor material, such as, silicon, germanium, or silicon-germanium, or III-V semiconductor compounds, such as, GaP, GaAs, or GaSb. In some embodiments, the substrate 100 may include a silicon-on-insulator (SOI) substrate or a germanium-on-insulator (GOI) substrate.

The active pattern 105 may protrude upwardly from the substrate 100. At least a portion of a sidewall of the active pattern 105 may be covered by the isolation pattern 130.

In example embodiments, the active pattern 105 may extend in the first direction D1, and a plurality of active patterns 105 may be spaced apart from each other in the second direction D2. A portion of the active pattern 105 may protrude above a height of the isolation pattern 130 in the third direction D3.

In example embodiments, the isolation pattern 130 may extend in the first direction D1 between adjacent active patterns of the active patterns 105, and a plurality of isolation patterns 130 may be spaced apart from each other in the second direction D2.

The active pattern 105 may include a material substantially the same as that of the substrate 100, and the isolation pattern 130 may include an oxide, for example, silicon oxide. However, embodiments are not limited thereto.

In example embodiments, a plurality of semiconductor patterns 124 may be disposed at a plurality of levels, respectively, and may be spaced apart from each other in the third direction D3 from an upper surface of the active pattern 105. Each of the plurality of semiconductor patterns 124 may extend in the first direction D1 to a given length. FIG. 2 and FIG. 3 show three semiconductor patterns 124 at three levels, respectively, however, the inventive concept may not be limited thereto.

Additionally, FIG. 3 shows semiconductor patterns 124 spaced apart from each other in the first direction D1 at each level on the active pattern 105 extending in the first direction D1, however, the inventive concept may not be limited thereto.

In example embodiments, the semiconductor pattern 124 may be a nano-sheet or nano-wire including a semiconductor material, for example, silicon or germanium. However, embodiments are not limited thereto. In example embodiments, the semiconductor pattern 124 may be a channel in a transistor, and may also be referred to as a channel.

The gate structure 300 may extend in the second direction D2 on the active pattern 105 and the isolation pattern 130, and may include a gate insulation pattern 270, a gate electrode 280 and a capping pattern 290.

In example embodiments, the gate structure 300 may surround a central portion in the first direction D1 of each of the semiconductor patterns 124, and may cover lower and upper surfaces and opposite sidewalls in the second direction D2 of each of the semiconductor patterns 124.

In example embodiments, the gate insulation pattern 270 may be disposed on a surface of each of the semiconductor patterns 124, upper surfaces of the active pattern 105 and the isolation pattern 130, a portion of a sidewall of the source/drain layer 210, and an inner sidewall of the gate spacer 180. The gate electrode 280 may be disposed in a space between the semiconductor patterns 124 spaced apart from each other in the third direction D3, a space between the active pattern 105 and a lowermost one of the semiconductor pattern 124, and a space between the gate spacers 180 spaced apart from each other in the first direction D1 on an uppermost one of the semiconductor patterns 124. For example, the gate electrode 280 may fill a space between the semiconductor patterns 124 spaced apart from each other in the third direction D3, a space between the active pattern 105 and a lowermost one of the semiconductor pattern 124, and a space between the gate spacers 180 spaced apart from each other in the first direction D1 on an uppermost one of the semiconductor patterns 124. The capping pattern 290 may contact upper surfaces of the gate insulation pattern 270 and the gate electrode 280, and the inner sidewall of the gate spacer 180.

Hereinafter, a portion of the gate structure 300 on the uppermost one of the semiconductor patterns 124 may be referred to as an upper portion, and a portion of the gate structure 300 below the upper portion may be referred to as a lower portion.

The gate insulation pattern 270 may include an oxide, for example, silicon oxide. The gate electrode 280 may include a metal nitride, for example, titanium nitride (TiN), titanium aluminum nitride (TiAlN), tantalum nitride (TaN), or tantalum aluminum nitride (TaAlN), a metal alloy, a metal carbide, a metal oxynitride, a metal carbonitride or a metal oxycarbonitride, for example, titanium aluminum carbide (TiAlC), titanium aluminum oxynitride (TiAlON), titanium aluminum carbonitride (TiAlCN), or titanium aluminum oxycarbonitride (TiAlOCN), or a low-resistance metal, for example, tungsten (W), aluminum (Al), copper (Cu), or tantalum (Ta). However, embodiments are not limited thereto. The capping pattern 290 may include an insulating nitride, for example, silicon nitride.

The gate spacer 180 may be disposed on each of opposite sidewalls in the first direction D1 of the upper portion of the gate structure 300. The gate spacer 180 may include an oxide, for example, silicon oxide, or an insulating nitride, for example, silicon nitride. The capping pattern 290 may include an insulating nitride, for example, silicon nitride. However, embodiments are not limited thereto.

The source/drain layer 210 may be disposed on a portion of the active pattern 105 adjacent to the gate structure 300, and may commonly contact sidewalls of the semiconductor patterns 124 at the plurality of levels, respectively, to be electrically connected thereto. An upper portion of the source/drain layer 210 may contact an outer sidewall of the gate spacer 180.

In example embodiments, the source/drain layer 210 may have a cross-section taken along the second direction D2, which may have a pentagon-like shape. In this case, the source/drain layer 210 may include single crystalline silicon-germanium doped with p-type impurities, and may be a source/drain layer of a PMOS transistor.

In other embodiments, the source/drain layer 210 may have a cross-section taken along the second direction D2, which may have a square with rounded corners or a circle shape. In this case, the source/drain layer 210 may include silicon doped with n-type impurities or silicon carbide doped with n-type impurities, and may be a source/drain layer of an NMOS transistor.

The first contact plug 360 may include a barrier pattern 325, a first liner 335, a second liner 345 and a conductive pattern 355 sequentially stacked in the third direction D3 on the source/drain layer 210, and may extend partially through the upper portion of the source/drain layer 210.

In example embodiments, the barrier pattern 325 may have a cup-shape, a lower surface and an outer sidewall of a lower portion of the barrier pattern 325 may contact an upper surface of the source/drain layer 210, and an outer sidewall of an upper portion of the barrier pattern 325 may contact a sidewall of a lower portion of the first insulating interlayer 230. Thus, an uppermost surface of the barrier pattern 325 may be higher than an uppermost surface of the source/drain layer 210. Also, an upper surface and an inner sidewall of the lower portion of the barrier pattern 325 may contact the first liner 335.

The uppermost surface of the barrier pattern 325 may be lower than uppermost surfaces of the first and second liners 335 and 345 and the conductive pattern 355 included in the first contact plug 360.

In example embodiments, the barrier pattern 325 may include a metal nitride, for example, titanium nitride or tantalum nitride. However, embodiments are not limited thereto.

The first liner 335 may be disposed on the barrier pattern 325, and may include a first portion contacting the barrier pattern 325 and a second portion not contacting the barrier pattern 325. The first and second portions of the first liner 335 may be stacked in the third direction D3, and may be connected with each other. The first liner 335 may include a metal, for example, cobalt, tungsten, or molybdenum. However, embodiments are not limited thereto.

In example embodiments, the first liner 335 may have a constant thickness. Thus, the first portion of the first liner 335 may be bent in the first direction D1 at the uppermost surface of the barrier pattern 325, and the first and the second portions of the first liner 335 may collectively have a staircase shape.

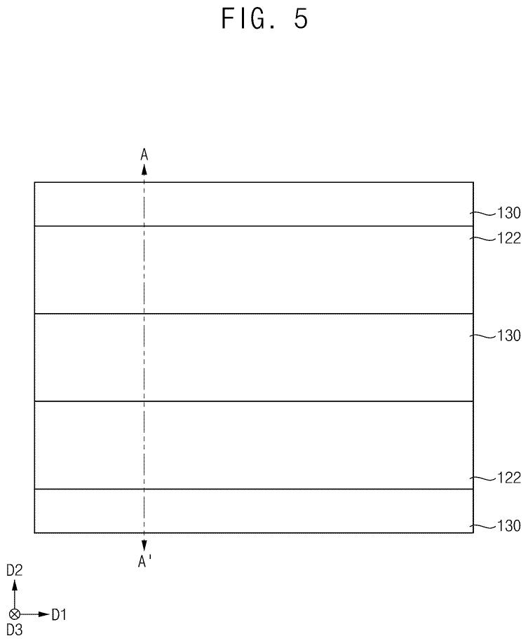

The first portion of the first liner 335 may have a first grain size and the second portion of the first liner 335 may have a second grain size. As illustrated below with reference to FIGS. 5 to 22, the first grain size of the first portion of the first liner 335 may be relatively small due to the influence of the barrier pattern 325 contacting the first portion of the first liner 335, and the second grain size of the second portion of the first liner 335 may be relatively large because the second portion of the first liner 335 does not contact the barrier pattern 325.

The second liner 345 may be disposed on the first liner 335, and an outer surface of the second liner 345 may be covered by the first liner 335. The second liner 345 may have a constant thickness, and may have a staircase shape which may be bent in the first direction D1 near the uppermost surface of the barrier pattern 325, as the first liner 335.

In example embodiments, the second liner 345 may include a metal, for example, cobalt, tungsten, or molybdenum, and may include the same metal as that of the first liner 335. In example embodiments, the metal included in the second liner 335 may be in an amorphous state.

The conductive pattern 355 may be disposed on the second liner 345. An outer surface of the conductive pattern 355 may be covered by the second liner 345. In example embodiments, the conductive pattern 355 may include a metal, for example, cobalt, tungsten, or molybdenum, and may include the same metal as that of the first and second liners 335 and 345. As illustrated, the conductive pattern 355 may be disposed on the second liner 345, which may include a metal in an amorphous state, and thus may not be affected by the crystallinity of the first liner 335. The conductive pattern 355 being substantially disassociated from the crystallinity of the first liner 335 may be formed to have a grain size that is greater than the first grain size of the first portion of the first liner 335.

The first insulating interlayer 230 may be disposed on the source/drain layer 210, and may cover a sidewall of the gate spacer 180 on a sidewall of the gate structure 300, and the second insulating interlayer 380 may be disposed on the first insulating interlayer 230, the gate structure 300, the gate spacer 180 and the first contact plug 360.

Each of the first and second insulating interlayers 230 and 380 may include insulating materials, for example, silicon oxycarbide (SiOC), silicon oxide (SiO₂), silicon nitride (SiN), silicon oxynitride (SiON), silicon carbonitride (SiCN), or silicon oxycarbonitride (SiOCN). However, embodiments are not limited thereto.

The second contact plug 390 may extend through the second insulating interlayer 380 and the capping pattern 290, and the second contact plug 390 may contact an upper surface of the gate electrode 280. The via 400 may extend through the second insulating interlayer 380, and the via 400 may contact an upper surface of the first contact plug 360. Each of the second contact plug 390 and the via 400 may include, for example, a metal and/or a metal nitride.

The semiconductor device may be a multi-bridge channel field effect transistor (MBCFET) including the semiconductor patterns 124 spaced apart from each other in the third direction D3 and serving as channels, respectively.

As illustrated herein, the conductive pattern 355 included in the first contact plug 360 may be disposed on the second liner 345, which may include a metal in an amorphous state, and the grain size of the metal in the conductive pattern 355 may not be affected by the grain size of the metal in the first liner 335. Thus, the conductive pattern 355 may have a grain size that is greater than the first grain size of the first portion of the first liner 335, and may have a relatively low resistance compared to the first liner 335.

In the first contact plug 360, the first portion of the first liner 335, which may have a relatively high resistance, may occupy a relatively small portion, while the conductive pattern 355, which may have a relatively low resistance, may occupy a relatively large portion, so that the first contact plug 360 may have an overall low resistance, and the semiconductor device including the first contact plug 360 may have an improved electrical characteristic.

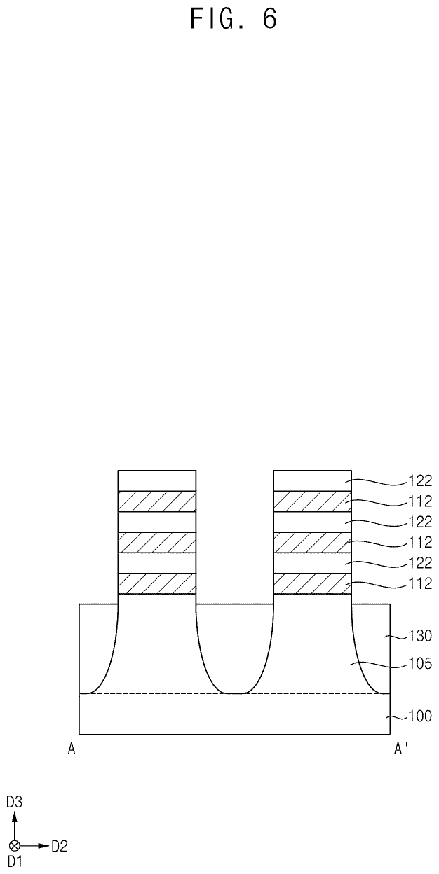

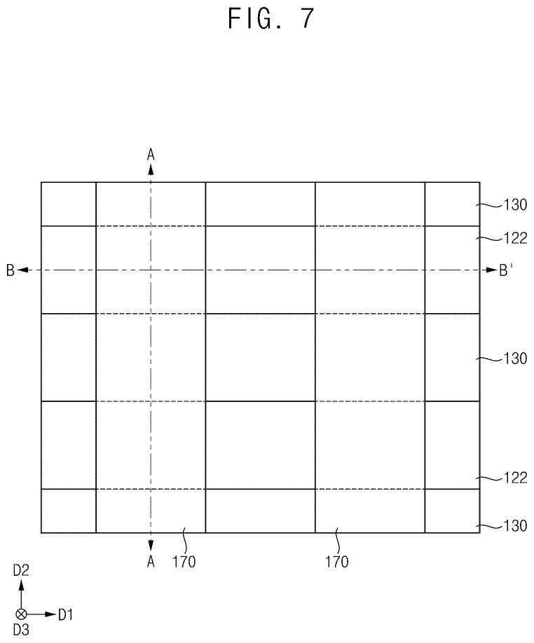

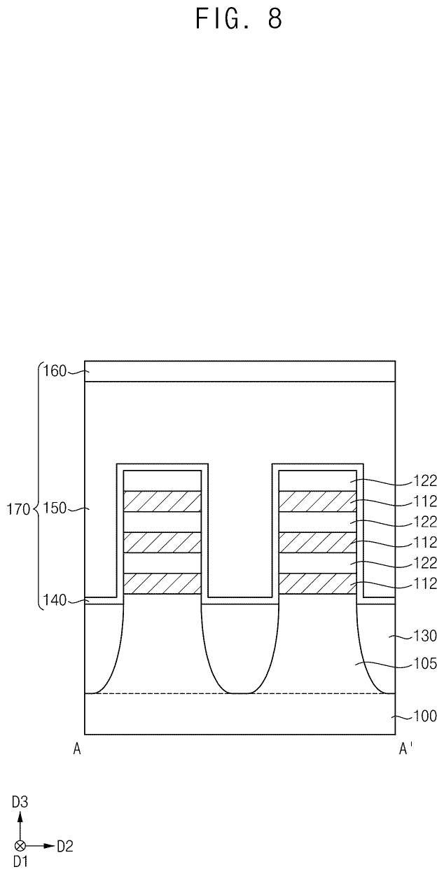

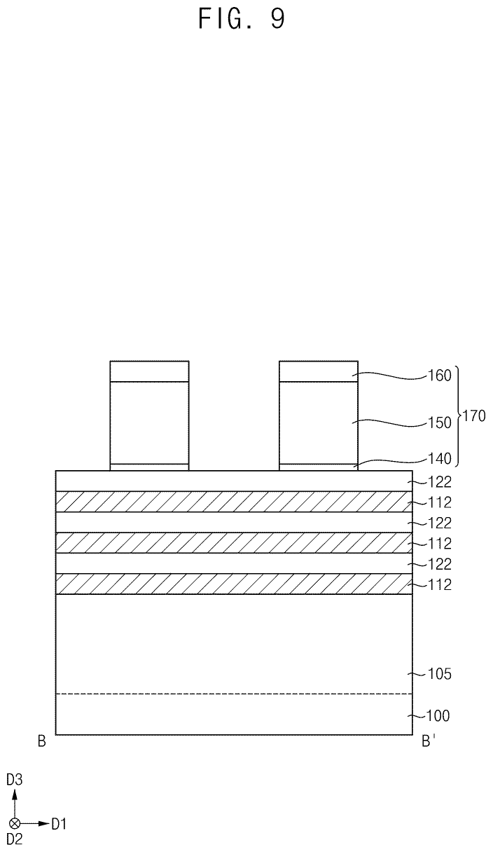

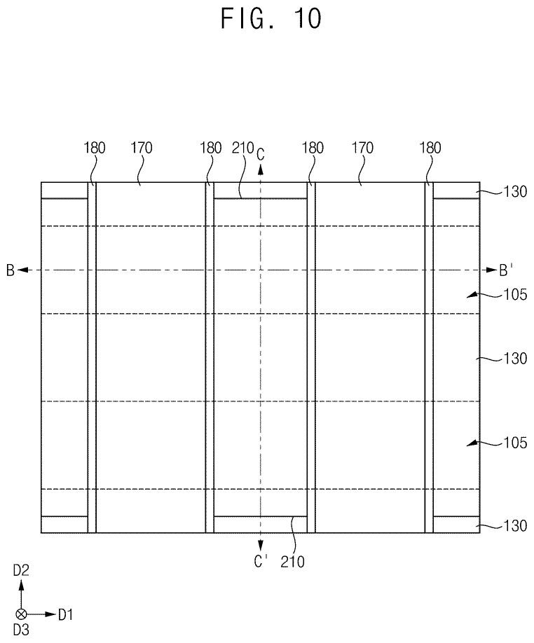

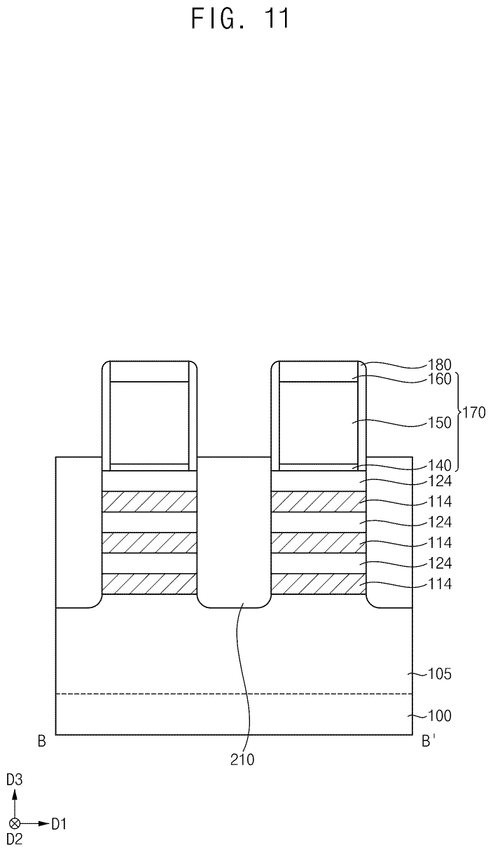

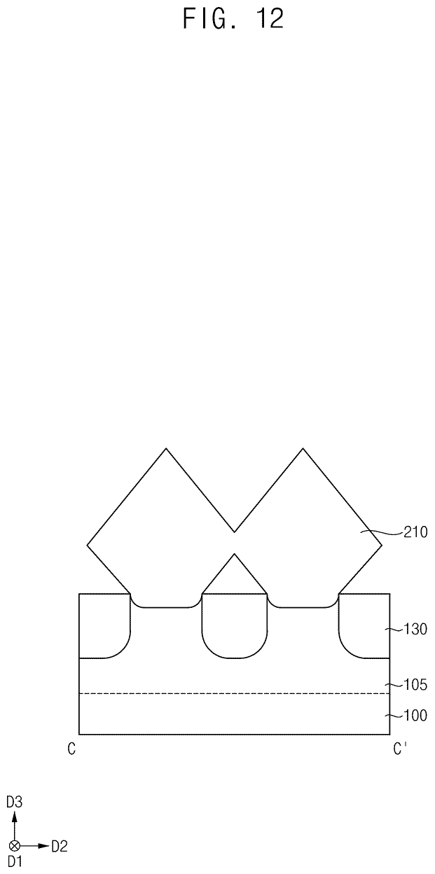

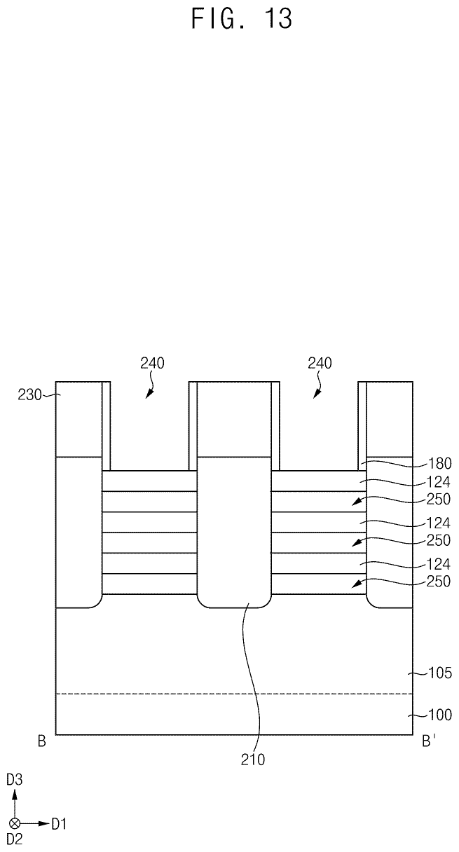

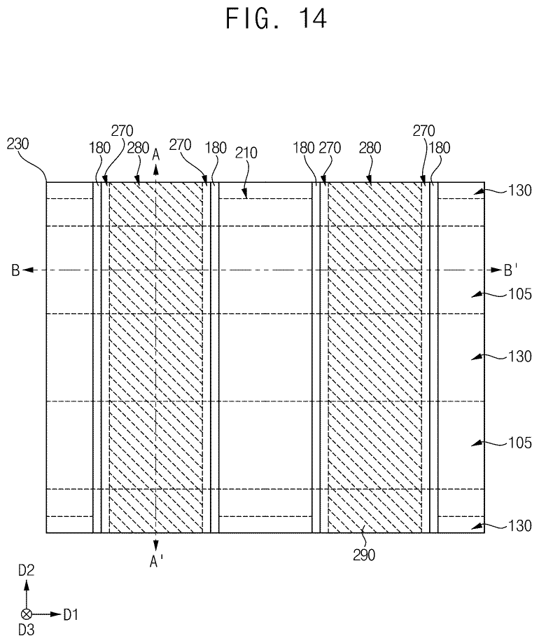

FIGS. 5 to 22 are plan views and cross-sectional views illustrating a semiconductor device in accordance with example embodiments. Particularly, FIG. 5, FIG. 7, FIG. 10 and FIG. 14 are the plan views, and FIG. 6, FIG. 8, FIG. 9, FIG. 11, FIG. 12, FIG. 13 and FIGS. 15-22 are the cross-sectional views.

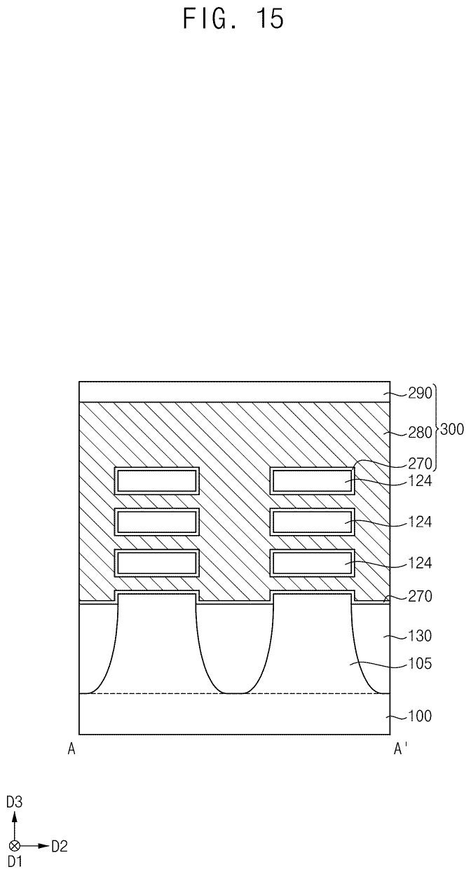

FIG. 6, FIG. 8 and FIG. 15 are cross-sectional views taken along lines A-A′ of corresponding plan views, respectively, FIG. 9, FIG. 11, FIG. 13 and FIGS. 16-22 are cross-sectional views taken along lines B-B′ of corresponding plan views, respectively, and FIG. 12 is a cross-sectional view taken along line C-C′ of a corresponding plan view.

Referring to FIG. 5 and FIG. 6, a first sacrificial layer and a semiconductor layer may be alternately and repeatedly stacked on a substrate 100, a first etching mask extending in the first direction D1 may be disposed on an uppermost one of the semiconductor layers, and the semiconductor layers, the sacrificial layers and an upper portion of the substrate 100 may be etched using the first etching mask.

Thus, an active pattern 105 extending in the first direction D1 may be disposed on the substrate 100, and a fin structure including sacrificial lines 112 and semiconductor lines 122 alternately and repeatedly stacked in the third direction D3 may be disposed on the active pattern 105. In example embodiments, the fin structure may extend in the first direction D1, and a plurality of fin structures may be spaced apart from each other in the second direction D2 on the substrate 100.

FIG. 6 shows three sacrificial lines 112 and three semiconductor lines 122 at three levels, respectively, however, the inventive concept may not be limited thereto. The semiconductor lines 122 may include, for example, silicon, and the sacrificial lines 112 may include a material having an etching selectivity with respect to the substrate 100 and the semiconductor lines 122, for example, silicon-germanium.

An isolation pattern 130 may be disposed on the substrate 100. The isolation pattern 130 may cover a sidewall of the active pattern 105.

Referring to FIG. 7, FIG. 8, and FIG. 9, a dummy gate insulation layer, a dummy gate electrode layer, and a dummy gate mask layer may be sequentially formed on the substrate 100. The dummy gate insulation layer, the dummy gate electrode layer, and the dummy gate mask layer may cover the fin structure and the isolation pattern 130. A second etching mask extending in the second direction D2 may be disposed on the dummy gate mask layer. The dummy gate mask layer may be etched using the second etching mask to form a dummy gate mask 160 on the substrate 100.

The dummy gate electrode layer and the dummy gate insulation layer may be etched using the dummy gate mask 160 as an etching mask to form a dummy gate electrode 150 and a dummy gate insulation pattern 140, respectively, on the substrate 100.

The dummy gate insulation pattern 140, the dummy gate electrode 150, and the dummy gate mask 160 sequentially stacked in the third direction D3 on the active pattern 105, and a portion of the isolation pattern 130 adjacent thereto, may collectively form a dummy gate structure 170.

In example embodiments, the dummy gate structure 170 may extend in the second direction D2 on the fin structure and the isolation pattern 130. The dummy gate structure 170 may cover an upper surface and opposite sidewalls in the second direction D2 of the fin structure.

In example embodiments, a plurality of dummy gate structures 170 may be spaced apart from each other in the first direction D1.

Referring to FIG. 10. FIG. 11, and FIG. 12, a gate spacer 180 may be disposed on a sidewall of the dummy gate structure 170.

More particularly, a gate spacer layer may be disposed on the substrate 100 having the fin structure, the isolation pattern 130, and the dummy gate structure 170 thereon, and the gate spacer layer may be anisotropically etched to form the gate spacer 180 covering sidewalls of the dummy gate structure 170. For example, the gate spacer 180 may be disposed on opposite sidewalls in the first direction D1 of the dummy gate structure 170.

The fin structure and an upper portion of the active pattern 105 may be etched using the dummy gate structure 170 and the gate spacer 180 as an etching mask to form a first opening.

Thus, the sacrificial lines 112 and the semiconductor lines 122 under the dummy gate structure 170 and the gate spacer 180 may be transformed into sacrificial patterns 114 and semiconductor patterns 124, respectively, and the fin structure extending in the first direction D1 may be divided into a plurality of parts spaced apart from each other in the first direction D1.

Hereinafter, the dummy gate structure 170, the gate spacer 180 on each of opposite sidewalls of the dummy gate structure 170, and the fin structure may collectively be referred to as a stack structure. In example embodiments, the stack structure may extend in the second direction D2, and a plurality of stack structures may be spaced apart from each other in the first direction D1.

A selective epitaxial growth (SEG) process may be performed using an upper surface of the active pattern 105, the sidewalls of the semiconductor patterns 124, and the sacrificial patterns 114 exposed by the first opening as a seed to form a source/drain layer 210 in the first opening.

In some example embodiments, the SEG process may be performed using a source gas, for example, disilane (Si₂H₆) gas and SiH₃CH₃ gas, etc. The SEG process may form a single crystal silicon carbide (SiC) layer as the source/drain layer 210. In this case, an n-type impurity source gas, for example, PH₃, may also be used to form a single crystalline silicon carbide layer doped with n-type impurities. Alternatively, the SEG process may be performed using a silicon source gas, for example, disilane (Si₂H₆) gas with the n-type impurity source gas, and in this case, a single crystalline silicon layer doped with n-type impurities may be formed as the source/drain layer 210.

In other embodiments, the SEG process may be performed using a silicon source gas, for example, dichlorosilane (SiH₂Cl₂) gas, a germanium source gas, for example, germane (GeH₄) gas, so that a single crystalline silicon-germanium layer may be formed as the source/drain layer 210. In this case, a p-type impurity source gas, for example, diborane (B₂H₆) gas, may also be used to form a single crystalline silicon-germanium layer doped with p-type impurities.

Referring to FIG. 13, a first insulating interlayer 230 may be disposed on the stack structure, the source/drain layer 210 and the isolation pattern 130. A planarization process may remove an upper portion of the first insulating interlayer 230 and the dummy gate mask 160 included in the dummy gate structure 170 and expose an upper surface of the dummy gate electrode 150 included in the stack structure.

At least a portion of the exposed dummy gate electrode 150 and the dummy gate insulation pattern 140 and the sacrificial patterns 114 under the dummy gate electrode 150 may be removed by performing, for example, a wet etching process and/or a dry etching process.

Thus, a second opening 240 exposing an inner sidewall of the gate spacer 180 and an upper surface of an uppermost one of the semiconductor patterns 124, and a third opening 250 exposing surfaces of the semiconductor patterns 124 and the upper surface of the active pattern 105 may be formed.

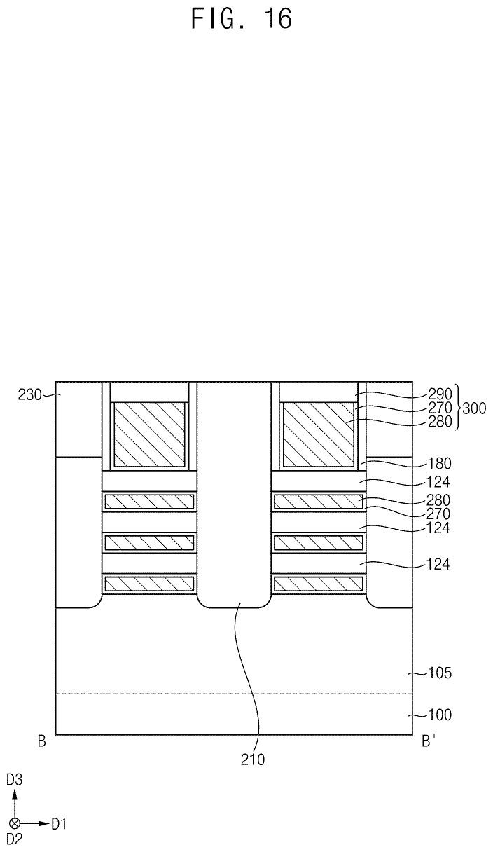

Referring to FIG. 14, FIG. 15, and FIG. 16, a gate insulation layer may be disposed on the inner wall of the gate spacer 180, the surfaces of the semiconductor patterns 124, the upper surface of the active pattern 105, an upper surface of isolation pattern 130 exposed by the second and third openings 240 and 250, and an upper surface of first insulating interlayer 230. A gate electrode layer may be disposed in a remaining portion of the second and third openings 240 and 250 on the gate insulation layer. For example, the gate electrode layer may fill the remaining portion of the second and third openings 240 and 250 on the gate insulation layer.

A planarization process may be performed on the gate electrode layer and the gate insulation layer to expose the upper surface of the first insulating interlayer 230, and a gate electrode 280 and a gate insulation pattern 270 may be formed in the second and third openings 240 and 250.

Upper portions of the gate insulation pattern 270 and the gate electrode 280 may be removed to form a first recess. A capping pattern 290 may be disposed in the first recess. Thus, a gate structure 300 including the gate insulation pattern 270, the gate electrode 280, and the capping pattern 290 may be formed.

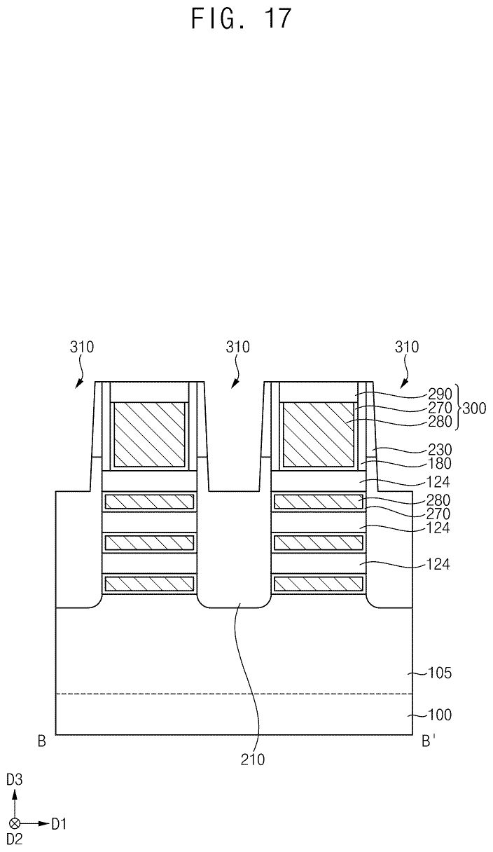

Referring to FIG. 17, a portion of the first insulating interlayer 230 may be removed to form a fourth opening 310 exposing an upper surface of the source/drain layer 210.

In an example embodiment, the fourth opening 310 may be formed by partially removing a portion of the first insulating interlayer 230 between neighboring ones of the gate structures 300, and thus the portion of the first insulating interlayer 230 may remain on a sidewall of the gate structures 300. However, the inventive concept may not be limited thereto, and in another example embodiment, the entire portion of the first insulating interlayer 230 between neighboring ones of the gate structures 300 may be removed by the fourth opening 310, so that a sidewall of the gate spacer 180 may be exposed.

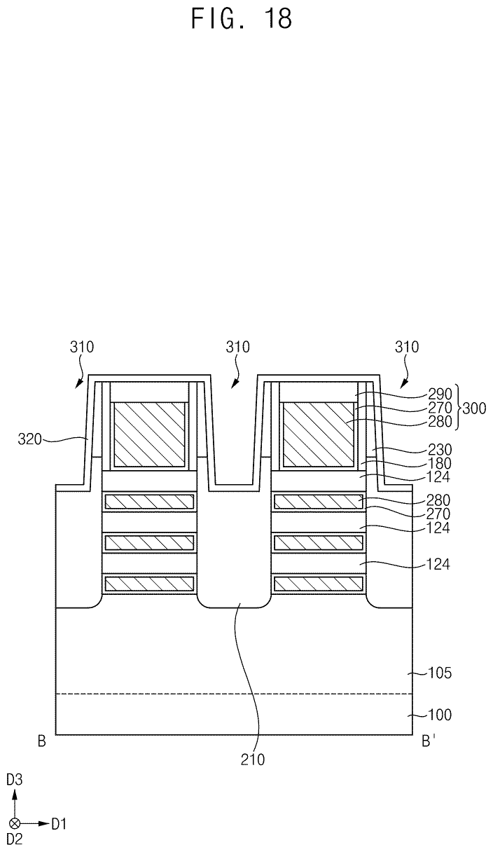

Referring to FIG. 18, a barrier layer 320 may be disposed on the upper surface of the source/drain layer 210, a sidewall and the upper surface of the first insulating interlayer 230, an upper surface of the gate spacer 180 and an upper surface of the gate structure 300.

In example embodiments, the barrier layer 320 may be formed by performing a deposition process, for example, a chemical vapor deposition (CVD) process, and may include a metal nitride, for example, titanium nitride (TiN).

In an example embodiment, an ohmic contact pattern (not illustrated) may be disposed between the source/drain layer 210 and the barrier layer 320.

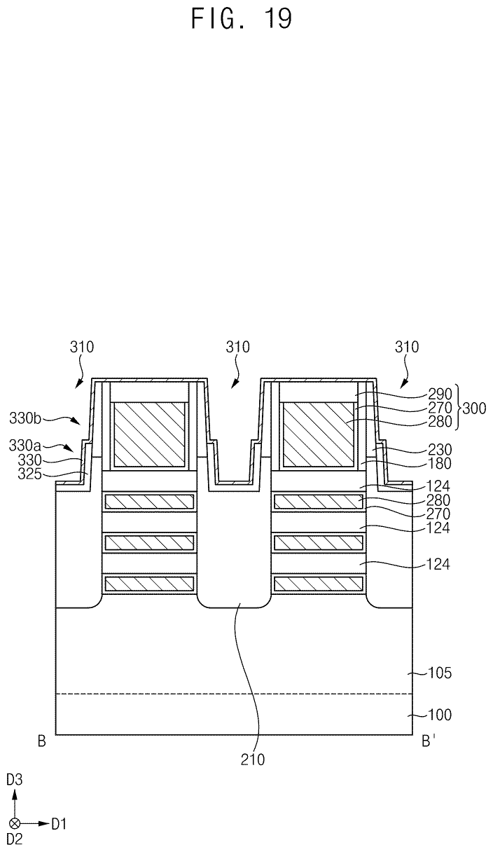

Referring to FIG. 19, a portion of the barrier layer 320 on the upper surfaces of the gate structure 300, the gate spacer 180 and the first insulating interlayer 230, and an upper portion of a sidewall of the first insulating interlayer exposed by the fourth opening 310 may be removed by performing an etching process, and thus, the barrier layer 320 may be transformed into a barrier pattern 325 on the upper surface of the source/drain layer 210 and a lower portion of the sidewall of the first insulating interlayer 230.

In an example embodiment, the barrier pattern 325 may have an uppermost surface lower than the upper surfaces of the gate spacer 180 and the gate structure 300, and higher than an uppermost surface of the source/drain layer 210.

A first liner layer 330 may be disposed on the upper surfaces of the gate structure 300 and the gate spacer 180, the upper surface and the sidewall of the first insulating interlayer 230, and an upper surface of the barrier pattern 325. Hereinafter, a lower portion of the first liner layer 330, which may contact the barrier pattern 325 may be referred to as a first portion 330a, and an upper portion of the first liner layer 330, which may not contact the barrier pattern 325 may be referred to as a second portion 330b.

In example embodiments, the first liner layer 330 may be conformally formed by performing a physical vapor deposition (PVD) process. Thus, the first portion of the first liner layer 330 may be bent in the first direction D1 at the uppermost surface of the barrier pattern 325, and the first portion 330a of the first liner layer 330 and the second portion 330b of the first liner layer 330 on the sidewall of the first insulating interlayer 230 may have a staircase shape.

In example embodiments, the first liner layer 330 may include a metal, for example, tungsten (W), and the metal of the first liner layer 330 may be in a crystalline state. In this case, the first portion 330a of the first liner layer 330, which may contact the barrier pattern 325, may have a grain size smaller than the second portion 330b of the first liner layer 330, which may not contact the barrier pattern 325. For example, the second portion 330b of the first liner layer 330 may extend from the first portion 330a of the first liner layer 330 disposed on an end portion of the barrier pattern 325. The end portion of the barrier pattern 325 may be an uppermost surface of the barrier pattern 325. The second portion 330b of the first liner layer 330 may be in contact with the first portion 330a of the first liner layer 330.

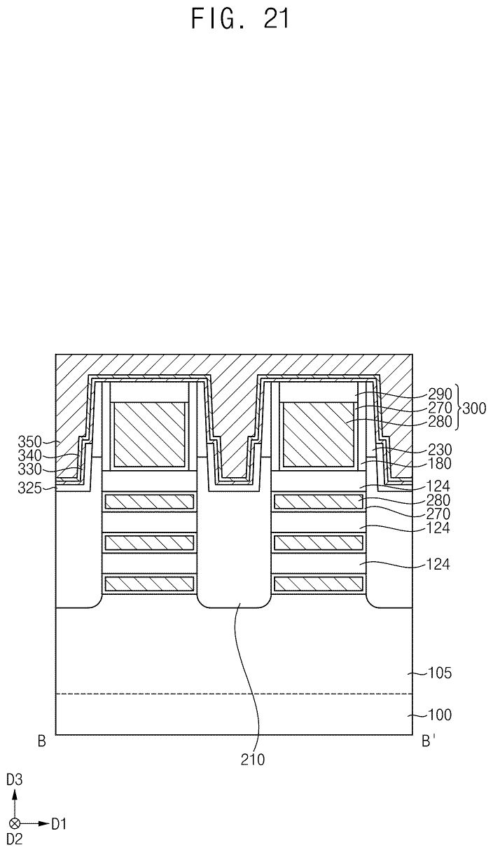

The first liner layer 330 may be a seed layer of the conductive layer 350 (refer to FIG. 21) that may be subsequently formed.

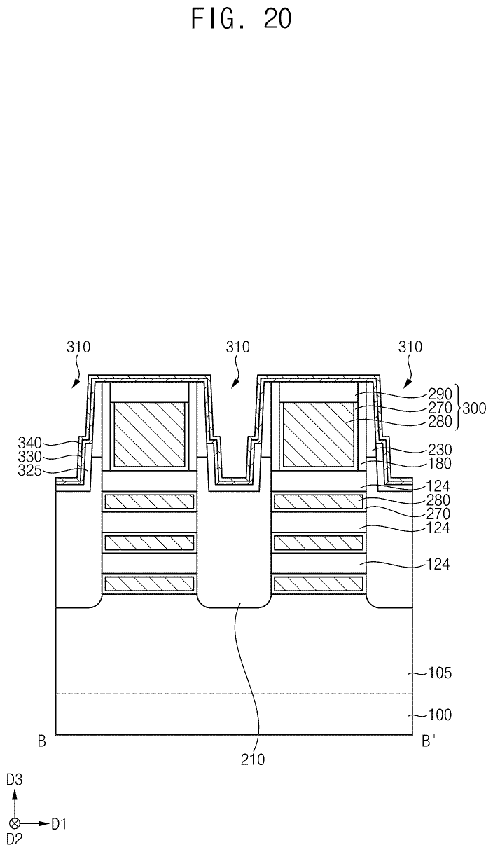

Referring to FIG. 20, a second liner layer 340 may be disposed on the first liner layer 330.

In example embodiments, the second liner layer 340 may be formed by performing an ALD process, and may be conformally disposed on the first liner layer 330. Thus, the second liner layer 340 may be bent in the first direction D1 at the uppermost surface of the barrier pattern 325 as the first liner layer 330, and a portion of the second liner layer 340 in the fourth opening 310 may have a staircase shape. In an embodiment, the ALD process may be performed under a pressure of about 5 torr.

In example embodiments, the second liner layer 340 may include the same material as that of the first liner layer 330, for example, a metal such as tungsten (W), however, the metal of the second liner layer 340 may be in an amorphous state.

Referring to FIG. 21, a conductive layer 350 may be disposed on the second liner layer 340.

In example embodiments, the conductive layer 350 may be disposed on the second liner layer 340 by performing a chemical vapor deposition (CVD) process, and may fill the fourth opening 310. During the CVD process, the second liner layer 340 may be a nucleation layer for the conductive layer 350. As illustrated herein, the second liner layer 340 may include the metal in the amorphous state, so that the conductive layer 350 on the second liner layer 340 may not be affected by the crystallinity of the second liner layer 340, and furthermore, by the crystallinity of the first liner layer 330 below the second liner layer 340. For example, the second liner layer 340 may substantially disassociate the conductive layer 350 from the crystallinity of the first liner layer 330 and from the crystallinity of the second liner layer 340.

In example embodiments, the conductive layer 350 may include the same material as that of the first liner layer 330 and the second liner layer 340, which is, a metal such as tungsten (W), and the metal included in the conductive layer 350 may have a large grain size.

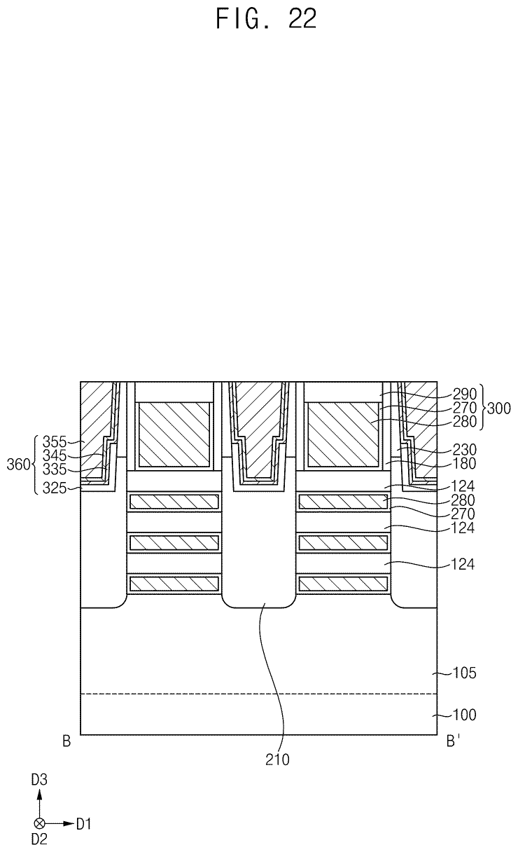

Referring to FIG. 22, a planarization process may be performed on the first liner layer 330, the second liner layer 340 and the conductive layer to expose the upper surfaces of the gate structure 300, the gate spacer 180 and the first insulating interlayer 230, and to form a first liner 335, a second liner 345 and a conductive pattern 355, respectively. In an embodiment, the conductive pattern 355 may include a lower portion adjacent to the source/drain layer 210 having a first width, and an upper portion having a second width greater than the first width. The upper portion may be disposed above the lower portion and away from the source/drain layer 210.

The barrier pattern 325, the first liner 335, the second liner 345 and the conductive pattern 355 may collectively form a first contact plug 360.

In example embodiments, the planarization process may include, for example, a chemical mechanical polishing (CMP) process and/or an etch back process.

Referring back to FIGS. 1 to 4, a second insulating interlayer 380 may be disposed on the first insulating interlayer 230, the first contact plug 360, the gate spacer 180 and the gate structure 300, an etching process may be performed to partially remove the second insulating interlayer 380 and the capping pattern 290 to form a fifth opening exposing an upper surface of the gate electrode 280, and the second insulating interlayer 380 may be partially removed to form a sixth opening exposing an upper surface of the first contact plug 360.

A second contact plug 390 and a via 400 may be formed to fill the fifth and sixth openings, respectively, and upper wirings electrically connected to the second contact plug 390 and the via 400 may be formed. By processes described herein, the semiconductor device may be manufactured.

As illustrated herein, a portion of the first insulating interlayer 230 may be removed to form the fourth opening 310 exposing the upper surface of the source/drain layer 210, the barrier layer 320 may be disposed in the fourth opening 310, the upper portion of the barrier layer 320 may be removed to form the barrier pattern 325, and the PVD process, the ALD process and the CVD process may sequentially performed to form the first liner layer 330, the second liner layer 340 and the conductive layer 350, respectively, on the barrier pattern 325. The planarization process may be performed on the first liner layer 330, the second liner layer 340 and the conductive layer 350 to expose the upper surfaces of the first insulating interlayer 230, the gate structure 300, and the gate spacer 180, and to form the first contact plug 360 including the barrier pattern 325, the first and second liners 335 and 345, and the conductive pattern 355.

The first liner 335 may be formed by the PVD process. The first portion of the first liner 335, which may contact the barrier pattern 325, may have a relatively small first grain size, and the second portion of the first liner 335, which may not contact the barrier pattern 325, may have a relatively large second grain size. If the conductive pattern 355 is formed directly on the first liner 335 by the CVD process, a portion of the conductive pattern 355 on the first portion of the first liner 335 may be affected by the small first grain size of the first portion, and the grain size of the portion of the conductive pattern 355 may also be small. The conductive pattern 355 having a small grain size may have a high overall resistance.

In example embodiments, the second liner 345 including a metal in an amorphous state may be formed on the first liner 335 by the ALD process, and the conductive pattern 355 formed by the CVD process may have a large grain size, and may not be affected by the crystallinity of the first liner 335 due to the second liner 345. Thus, the conductive pattern 355 may have a low overall resistance.

The ALD process for forming the second liner 345 may be performed at a low pressure of about 5 torr, and the partial pressure of the remaining materials after the process may be low. Therefore, even in a case that a CVD process is performed subsequently using a highly reactive material such as WF₆ or WCl₆, products such as HF or HCl may be present in small amounts, and damage to surrounding structures due to the diffusion of the highly reactive material thereto may be reduced.

Additionally, the second liner 345 may be formed by the ALD process to have a uniform thickness. In a case that the conductive pattern 355 may be formed by the CVD process, an overhang that may result from a PVD process may be avoided.

As a result, the contact plug 360 including the conductive pattern 355 and the second liner 345 may have an improved electrical characteristic.

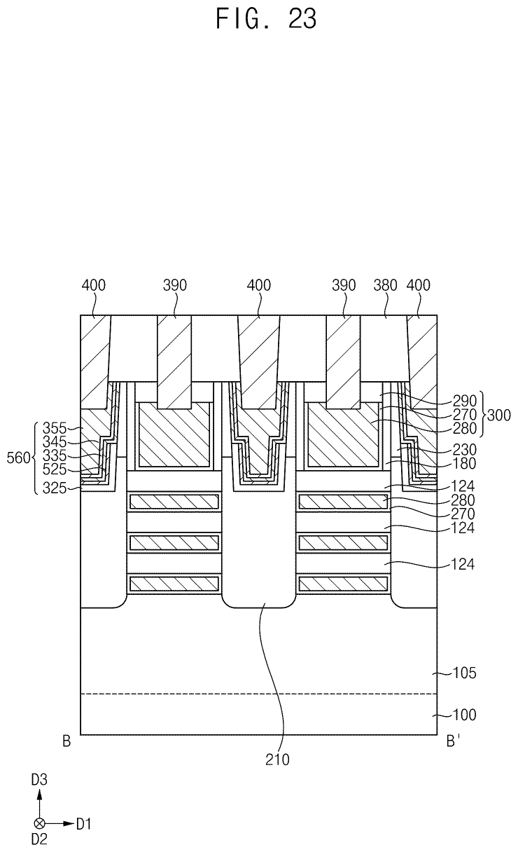

FIG. 23 is a cross-sectional view illustrating a semiconductor device in accordance with example embodiments, which corresponds to FIG. 3. This semiconductor device may include elements substantially the same as, or similar to those of the semiconductor device illustrated with reference to FIGS. 1 to 4 except for further including a third liner 525. Thus, like reference numerals refer to like elements, and repeated explanation thereof may be omitted herein.

Referring to FIG. 23, the semiconductor device may include a third contact plug 560 on the substrate 100.

The third contact plug 560 may include the barrier pattern 325, the third liner 525, the first liner 335, the second liner 345 and the conductive pattern 355 sequentially stacked in the third direction D3 on the source/drain layer 210.

The third liner 525 may be disposed on the barrier pattern 325, and may have a cup shape. An uppermost surface of the third liner 525 may be substantially coplanar with the uppermost surface of the barrier pattern 325. Additionally, the third liner 525 may have a uniform thickness.

In example embodiments, the third liner 525 may include a metal, for example, cobalt, tungsten, or molybdenum.

The first liner 335 may be disposed on the third liner 525 and the barrier pattern 325, and may include a first portion, which may contact the third liner 525 and the barrier pattern 325, and a second portion, which may not contact the third liner 525 and the barrier pattern 325. The first and second portions (see first portion 330a and second portion 330b of FIG. 19) of the first liner 335 may be stacked in the third direction D3, and may be connected to each other. The first liner 335 may include a metal, for example, cobalt, tungsten, or molybdenum.

The first portion of the first liner 335 may have a first grain size, and the second portion of the first liner 335 may have a second grain size, which may be larger than the first grain size.

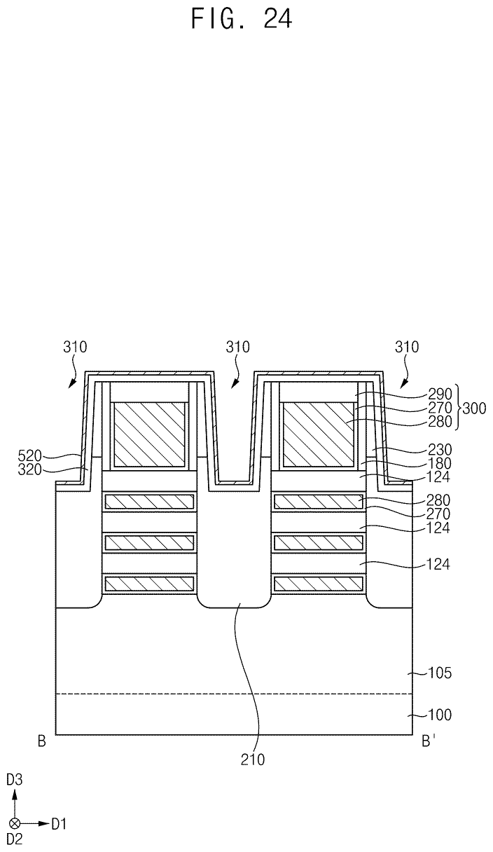

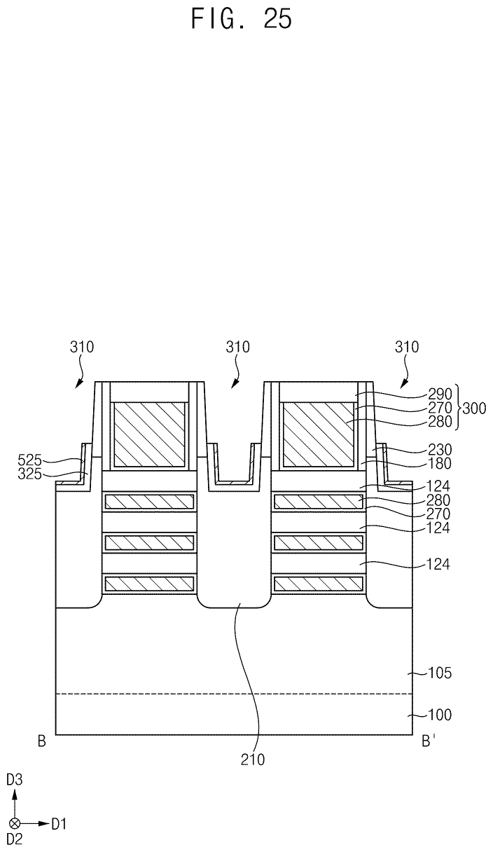

FIG. 24 and FIG. 25 are cross-sectional views illustrating a method of manufacturing a semiconductor device in accordance with example embodiments.

A method according to FIG. 24 and FIG. 25 may include processes substantially the same as, or similar to those illustrated with reference to FIGS. 5 to 22 and FIGS. 1 to 4, and thus repeated explanations thereof may be omitted.

Referring to FIG. 24, a third liner layer 520 may be formed on the barrier layer 320 by a PVD process.

In example embodiments, the third liner layer 520 may include a metal, for example, cobalt, tungsten, or molybdenum. However, embodiments are not limited thereto.

Referring to FIG. 25, first portions of the barrier layer 320 and a portion of the third liner layer 520 disposed on the upper surfaces of the gate spacer 180 and the first insulating interlayer 230 may be removed, and second portion of the barrier layer 320 and a portion of the third liner layer 520 disposed on the upper portion of the sidewall of the first insulating interlayer 230 exposed by the fourth opening 310 may be removed. The first portions and the second portions of the barrier layer 320 and a portion of the third liner layer 520 may be removed by an etching process to form the barrier pattern 325 and a third liner 525, respectively.

Accordingly, the uppermost surface of the barrier pattern 325 and an uppermost surface of the third liner 525 may be formed to be substantially coplanar with each other. The uppermost surface of the barrier pattern 325 and the uppermost surface of the third liner 525 may be lower than the upper surfaces of the gate spacer 180 and the gate structure 300, and higher than the uppermost surface of the source/drain layer 210. For example, an interface between the source/drain layer 210 and the first insulating interlayer 230 may be protected by the barrier pattern 325 and the third liner 525.

Referring back to FIG. 23, processes that are substantially the same as, or similar to the processes illustrated with reference to FIGS. 19 to 22 and FIGS. 1 to 4 may be performed, and the semiconductor device may be manufactured.

The foregoing is illustrative of example embodiments and is not to be construed as limiting thereof. Although example embodiments have been described, those skilled in the art will readily appreciate that many modifications are possible without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures.

What is claimed is:

1. A semiconductor device comprising:
a substrate;
a gate structure disposed on the substrate;
a source/drain layer disposed on the substrate adjacent to the gate structure; and
a contact plug including:
a barrier pattern disposed on the source/drain layer;
a first liner disposed on the barrier pattern, the first liner comprising:
a first portion extending along a surface of the barrier pattern, the first portion having a first grain size; and
a second portion extending from the first portion disposed on an end portion of the barrier pattern, the second portion in contact with the first portion, and having a second grain size greater than the first grain size;
a second liner disposed on the first liner, the second liner including a metal; and
a conductive pattern disposed on the second liner, the conductive pattern including the metal.

2. The semiconductor device according to claim 1, wherein the first portion and the second portion of the first liner are conformally formed with a first thickness and a second thickness, respectively, and
the first thickness is greater than the second thickness.

3. The semiconductor device according to claim 1, wherein the second liner includes the metal in an amorphous state.

4. The semiconductor device according to claim 1, wherein the first liner includes the metal in a crystalline state.

5. The semiconductor device according to claim 1, wherein an uppermost surface of the barrier pattern is higher than an uppermost surface of the source/drain layer.

6. The semiconductor device according to claim 1, further comprising an ohmic contact pattern disposed between the source/drain layer and the barrier pattern.

7. The semiconductor device according to claim 1, further comprising a gate spacer disposed on a sidewall of the gate structure, and
the barrier pattern and the first liner are disposed on a sidewall of the gate spacer.

8. The semiconductor device according to claim 1, wherein the metal includes tungsten (W), and
the barrier pattern includes a titanium nitride (TiN).

9. The semiconductor device according to claim 1, wherein the conductive pattern has a third grain size, and
the third grain size is greater than the first grain size and the second grain size.

10. The semiconductor device according to claim 1, further comprising a plurality of channels on the substrate and spaced apart from each other in a vertical direction substantially perpendicular to an upper surface of the substrate, and
the gate structure at least partially surrounds the plurality of channels.

11. A semiconductor device comprising:
a substrate;
a plurality of channels disposed on the substrate, the plurality of channels spaced apart from each other in a vertical direction substantially perpendicular to an upper surface of the substrate;
a gate structure disposed on the substrate, the gate structure surrounding an upper surface, a lower surface, and a sidewall surface of a portion of each of the plurality of channels;
a source/drain layer disposed on the substrate at opposite sides of the gate structure;
an insulating interlayer disposed on the source/drain layer; and
a contact plug extending through the insulating interlayer and contacting an upper surface of the source/drain layer, the contact plug including:
a conductive pattern including a metal;
a second liner covering a lower surface and a sidewall of the conductive pattern, the second liner including the metal in an amorphous state;
a first liner including:
a first portion covering a lower surface and a lower sidewall of the second liner, the first portion including the metal having a first grain size; and
a second portion extending from the first portion and contacting the first portion, the second portion covering an upper sidewall of the second liner and including the metal having a second grain size greater than the first grain size; and
a barrier pattern covering a lower surface and a sidewall of the first portion of the first liner.

12. The semiconductor device according to claim 11, wherein the conductive pattern includes a lower portion having a first width, and an upper portion having a second width greater than the first width.

13. The semiconductor device according to claim 11, wherein the second portion of the first liner extends from the first portion disposed on an end portion of the barrier pattern, wherein the end portion includes an uppermost surface of the barrier pattern.

14. The semiconductor device according to claim 11, wherein an upper portion of the barrier pattern contacts the insulating interlayer.

15. A method of manufacturing a semiconductor device, the method comprising:
forming a gate structure and a source/drain layer on a substrate;
forming an insulating interlayer on the substrate to cover an upper surface of the source/drain layer and a sidewall of the gate structure;
removing a portion of the insulating interlayer to form an opening exposing the upper surface of the source/drain layer;
forming a barrier pattern on a bottom and a lower sidewall of the opening and exposing a portion of the insulating interlayer forming an upper sidewall of the opening;
forming a first liner layer on the barrier pattern and the upper sidewall of the opening by a physical vapor deposition (PVD) process;
forming a second liner layer on the first liner layer by an atomic layer deposition (ALD) process; and
forming a conductive pattern on the second liner layer.

16. The method according to claim 15, wherein forming the barrier pattern includes:
forming a barrier layer on the bottom and a sidewall of the opening, the insulating interlayer and an upper surface of the gate structure; and
removing an upper portion of the barrier layer disposed on a portion of the insulating interlayer and the upper surface of the gate structure.

17. The method according to claim 15, wherein the first liner layer, the second liner layer and the conductive pattern include substantially a same metal.

18. The method according to claim 17, wherein the second liner layer includes the metal in an amorphous state.

19. The method according to claim 15, wherein a portion of the first liner layer that overlaps the barrier pattern in a horizontal direction substantially parallel to an upper surface of the substrate has a first grain size smaller than a second grain size of a portion of the first liner layer disposed on the upper sidewall of the opening.

20. The method of claim 15, wherein forming the conductive pattern includes:
forming a conductive layer on the second liner layer by a chemical vapor deposition (CVD) process; and
planarizing the conductive layer by performing a chemical mechanical polishing (CMP) process exposing an upper surface of the insulating interlayer and an upper surface of the gate structure,
wherein, during the CMP process, a portion of the first liner layer and a portion the second liner layer on the upper surfaces of the insulating interlayer and the gate structure are removed to form a first liner and a second liner, respectively.
